(19) United States
(12) Patent Application Publication
(10) Pub. No.: US 2017/0042061 A1
(43) Pub. Date: Feb. 9, 2017

(54) SERVER FAN FLAP AND SHUTTER SYSTEM FOR PREVENTION OF AIR FLOW DIVERSION

(71) Applicant: Quanta Computer Inc., Taoyuan City (TW)

(72) Inventors: Chao-Jung CHEN, Taoyuan City (TW); Chih-Ming CHEN, Taoyuan City (TW); Hsu-Feng LEE, Taoyuan City (TW)

(21) Appl. No.: 15/047,157

(22) Filed: Feb. 18, 2016

Related U.S. Application Data
(60) Provisional application No. 62/200,282, filed on Aug. 3, 2015.

(51) Int. Cl. H05K 7/20

(52) U.S. Cl. CPC H05K 7/20181; H05K 7/20736

(57) ABSTRACT

A server rack can include a plurality of server chassis. The server chassis can form a opening configured to receive a removable fan through the opening. The removable fan can including a plurality of shutters, the plurality of shutters can be automatically transitionable between an open configuration and a closed configuration. In the open configuration the fan can draw in or push out air to cool the components located within the server chassis. In the closed configuration the shutters can prevent air from entering or exiting the server chassis. A flap can be coupled to the server chassis and automatically transitionable between an open configuration and a closed configuration. In the open configuration the fan is inserted into the server chassis and the flaps are opened into the server chassis. In the closed configuration the fan is removed from the server chassis and the flaps can prevent air from entering or exiting the server chassis.

### CROSS REFERENCE TO RELATED APPLICATIONS

The instant application claims priority to U.S. Provisional Application No. 62/200,282 entitled “Fan flap design on server system for prevent airflow recirculation” filed Aug. 3, 2015, the contents of which is herein expressly incorporated by reference in its entirety.

### FIELD

The subject matter herein generally relates to server chassis. More specifically, the subject matter herein relates to a shutter and flap system for preventing airflow diversion during a fan failure or replacement.

### BACKGROUND

A server rack can include multiple server chassis. Each server chassis can include a plurality of removable fans for cooling the server components. When a removable fan malfunctions or fails, airflow may be diverted through the malfunctioning fan, preventing the server components from being properly cooled. Further, when a removable fan is removed (e.g., hot swapped) from the server chassis, the opening in the server chassis (configured to receive the removable fan) may enable airflow to be diverted through the opening, again preventing the server components from being properly cooled.

### SUMMARY

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

Disclosed are systems and apparatus for enabling proper airflow for a server chassis. The server chassis can include a plurality of removable fans configured to adequately cool the components located within the server chassis. While operating properly, the removable fans require unobstructed access to the air outside and inside the server chassis to enable adequate air circulation to provide proper cooling of the components. While the present disclosure discusses embodiments directed at removable fans this should not be limiting. The present disclosure can be enabled for any hardware module that is hot swappable in a server chassis.

When a removable fan malfunctions (or fails), the air outside and inside the server chassis can be obstructed to prevent the airflow from being diverted from the other removable fans (operating properly) to enable adequate cooling of the server components. Thus, in some embodiments, the removable fans can be equipped with one or more shutters. The shutters can have an open configuration and a closed configuration. In the open configuration, the shutters can enable unobstructed airflow through the removable fan. In the closed configuration, the shutters can obstruct or prevent airflow through the removable fan. The shutters can automatically transition between the open configuration and the closed configuration by the operating state of the removable fan.

When a removable fan has malfunctioned (or failed) it will need to be replaced. During the replacement of the removable fan, the opening in the server chassis to which the removable fan is inserted can be exposed. The opening can divert airflow from the other removable fans operating properly causing the server components within the server chassis to overheat (i.e., not be adequately cooled). Therefore, in some embodiments, the server chassis can be equipped with one or more flaps configured to prevent airflow by covering the opening. The flaps can be coupled to the server chassis by a shaft. The flaps can be configured to automatically transition between the open configuration and the closed configuration by a spring mechanism coupled to the flaps and the shaft. The flaps can further be configured to open and close vertically or horizontally. In the some embodiments, each opening of the server chassis can include at least one flap.

At least one embodiment can include, a system comprising a server chassis having an opening configured to receive at least one removable component through the opening, the at least one removable component including at least one shutter, the at least one shutter transitionable between an open configuration and a closed configuration, wherein in the closed configuration the at least one shutter covers the removable component, and at least one flap coupled to the server chassis and transitionable between an open configuration and a closed configuration, wherein in the closed configuration the at least one flap covers the opening.

Other embodiments can include, the removable component includes a fan. The server chassis having a plurality of openings configured to receive a plurality of removable components through the plurality of openings. The at least one shutter is in the open configuration when the removable component is operating. The at least one shutter is in the closed configuration when the removable component is not operating. A shaft for coupling the at least one flap to the server chassis. A spring mechanism for actuating the at least one flap between the open configuration and a closed configuration. The spring mechanism is coupled to the at least one flap and to the shaft. The at least one flap is configured in the open configuration when the removable component is inserted into the opening of the server. The at least one flap is configured in the closed configuration when the removable component is not inserted into the opening of the server chassis. The server chassis includes two or more flaps.

### BRIEF DESCRIPTION OF THE DRAWINGS

Implementations of the present technology will now be described, by way of example only, with reference to the attached figures, wherein:

FIG. 1 is an isometric view of an example embodiment of a server chassis including removable fans;

FIG. 2 is an back view of an example embodiment of a server chassis including removable fans;

FIG. 3 is an isometric view of an example embodiment of removable fans including shutters;

FIG. 4 is an isometric view of an example embodiment of a server chassis including flaps;

FIG. 5 is an isometric view of an example embodiment of a server chassis including flaps; and

FIG. 6 is a detailed view of an example embodiment of a server chassis including flaps.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

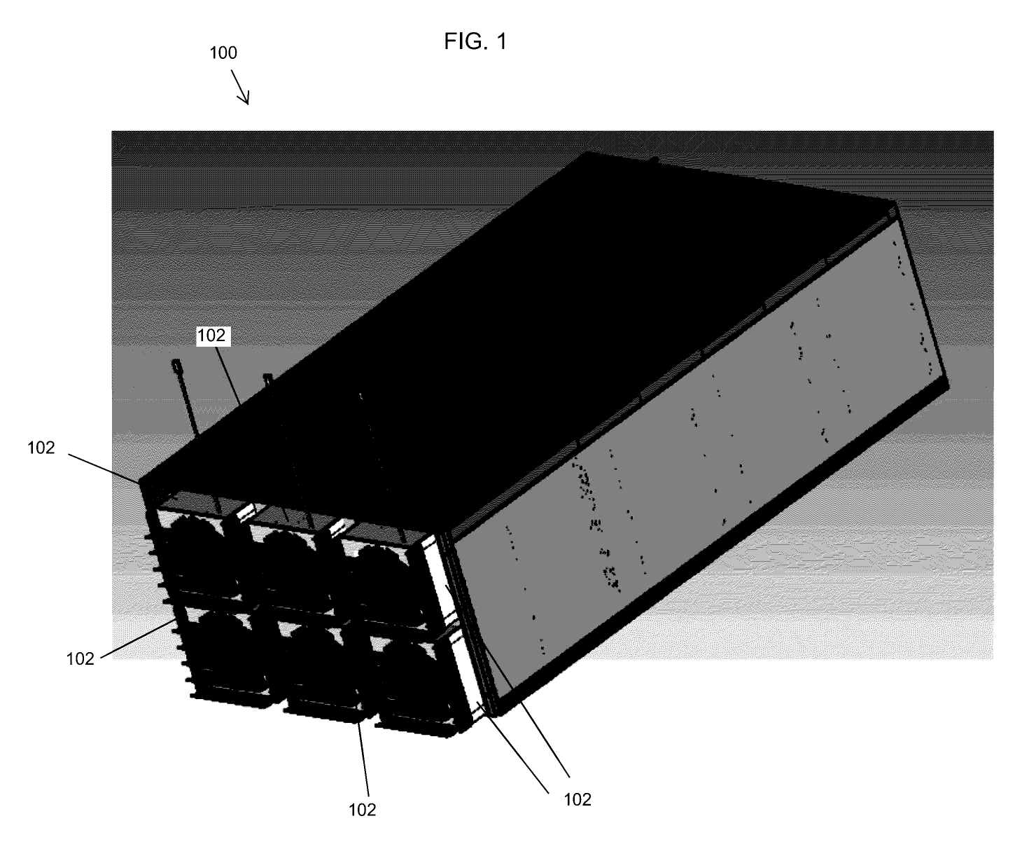

FIG. 1 illustrates an example embodiment of a server chassis. Server chassis 100 can be configured to have a plurality of removable fans 102. The removable fans 102 can be configured to circulate air (e.g., airflow pattern) to enable the cooling of the components within the server chassis. A proper airflow pattern is important for adequately cooling the components within the server chassis 100. In some embodiments, the server chassis 100 can be configured to mount into a rack mounted system. Rack mounted systems (e.g., 19-inch rack, etc.) can be configured to receive a plurality of different hardware modules (e.g., server chassis, etc.) by various removable attachments (e.g., rails, etc.). Rack mounted systems can have a variety of airflow patterns. For example, intake air on the front of the rack (front intakes) and output air on the rear of the rack (rear exhausts

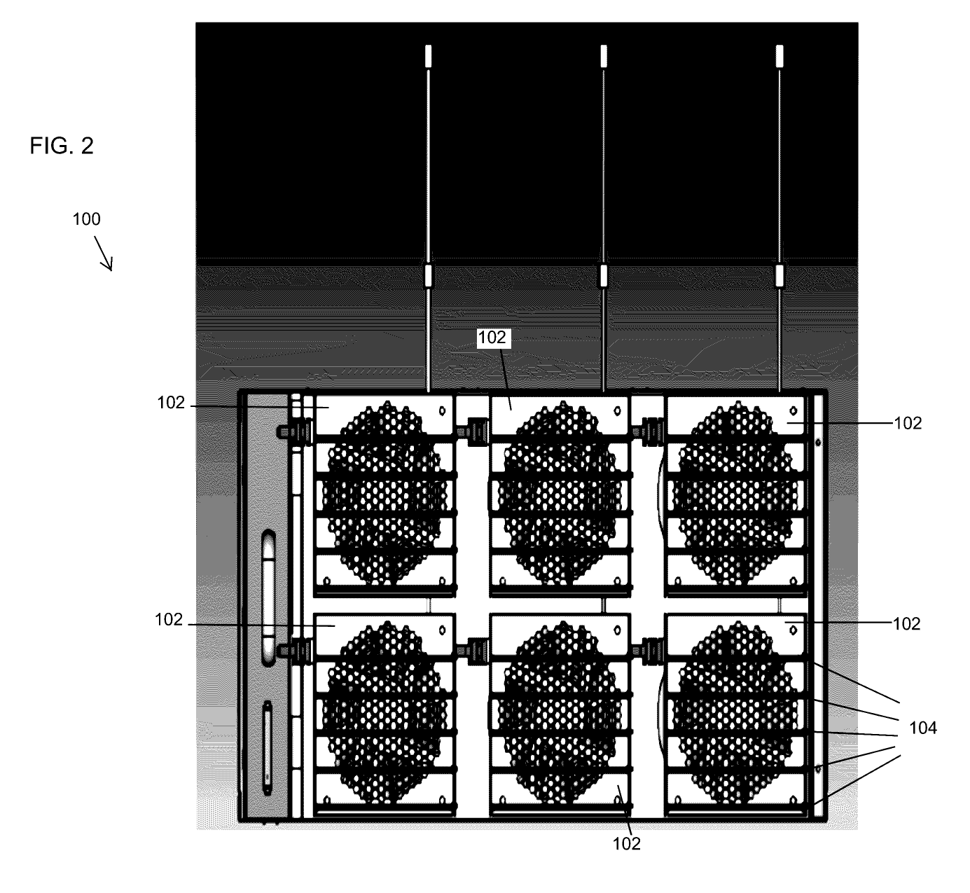

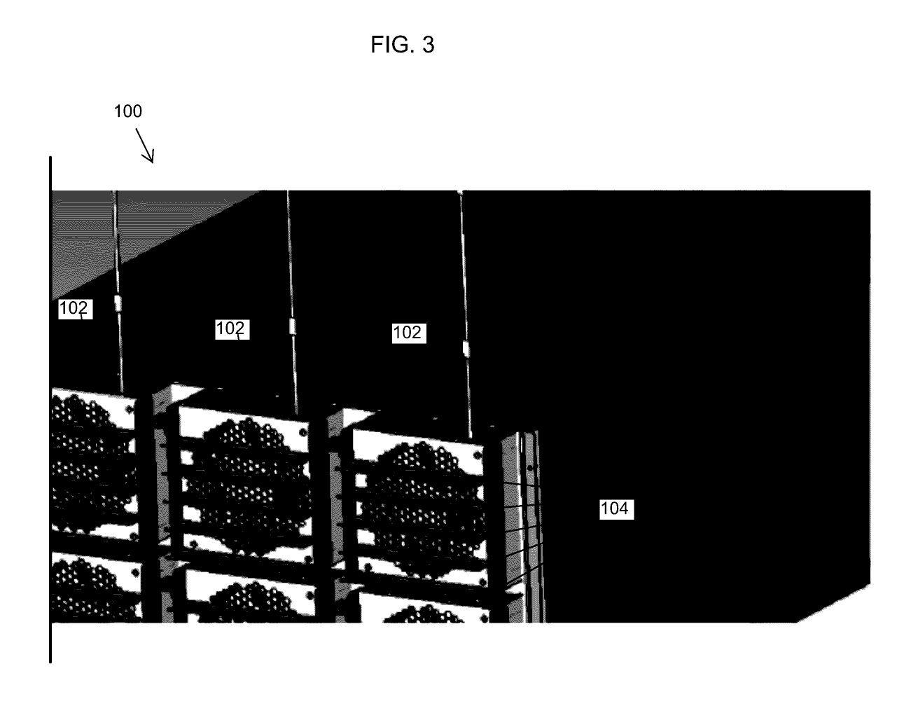

FIG. 2 and FIG. 3 illustrate other views of server chassis 100. As shown in FIGS. 2 and 3, server chassis 100 can include one or more removable fans 102 for circulating air to enable the cooling of components within the server chassis. Removable fans 102 can include one or more shutters 104. The shutters 104 can operate in an open configuration (i.e., enabling airflow) and a closed configuration (i.e., restricting airflow). In at least one embodiment, the shutters 104 can be actuated by removable fans 102. For example, when a removable fan 102 is operational (i.e., outputs air), the shutters 104, in response to the output of air, can open. Alternatively, when a removable fan 102 is not operational (i.e., does not output air), the shutters 104, in response to no output of air, can close. In another embodiment, the shutters 104 can be actuated by a mechanical switch. For example, the mechanical switch can be a timing-based mechanical switch, a pressure sensitive mechanical switch, or any other type of mechanical switch that can be configured to actuate the shutters between the two configurations. In another embodiment, the shutters 104 can be actuated by an electrical switch. For example, the electrical switch (e.g., pressure, temperature, flow, relay, etc.) can be any of type that can receive an electronic signal and actuate the shutters between the two configurations, in response to receiving the electronic signal transmit a signal. In another embodiment, the shutters 104 can be actuated based on the internal temperature of the server chassis. In another embodiment, the shutters 104 can be actuated by a processor within the server chassis. For example, a management controller can be incorporated into server chassis 100 and can be configured to control operation of the shutters 104. In still other embodiments, the operation of the shutters 104 can be controlled by an external management controller, forwarding signals to various removable fans 102.

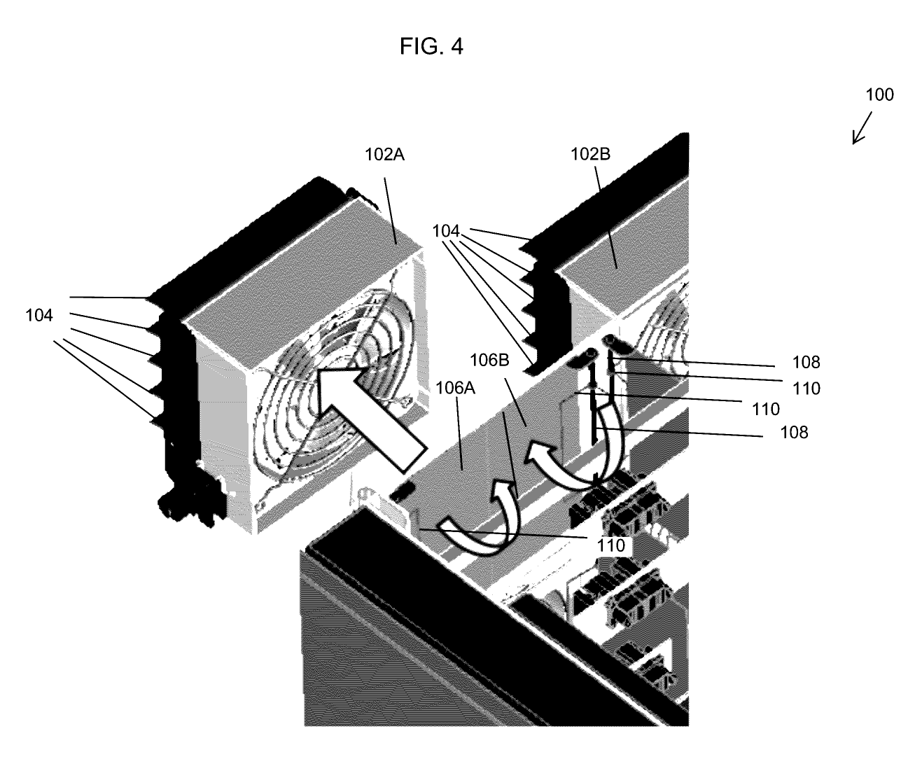

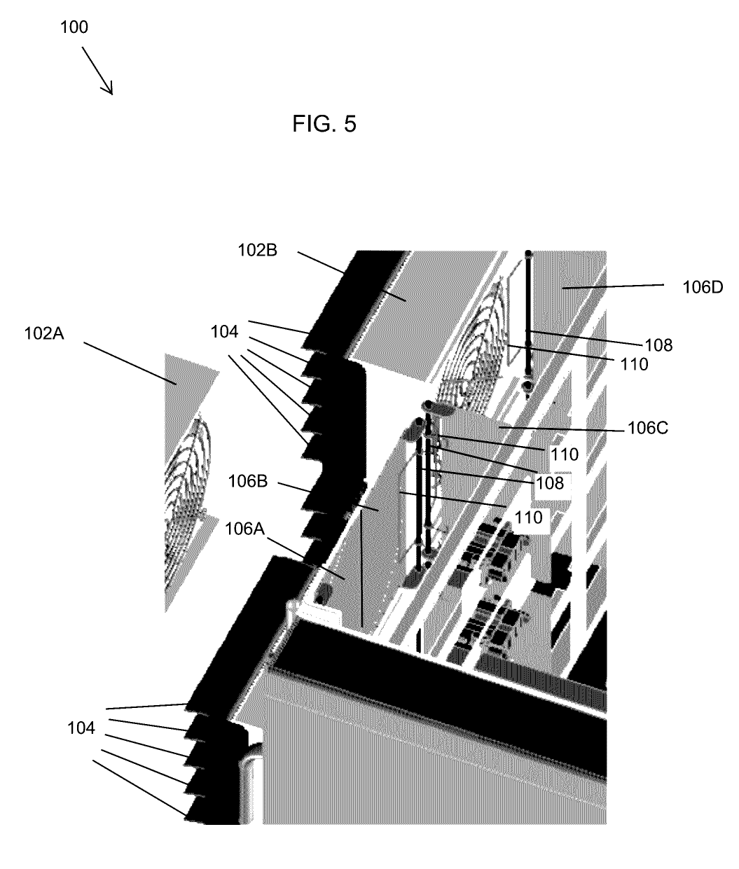

FIG. 4 and FIG. 5 illustrate an internal view of a server chassis with flaps in the open configuration and the closed configuration. Server chassis 100 can include one or more removable fans 102. Removable fans 102 can be hot swappable (i.e., they can be removed from the server chassis while the server is still operational).

In one embodiment, the flaps 106 can be in the closed configuration when removable fan 102 is removed from the server chassis 100. For example, removable fan 102A can be removed from the server chassis 100. Flaps 106A and 106B are coupled to the server chassis 100 by shafts 108. Spring 110 can be coupled to shaft 108. The flaps 106A and 106B can be configured to be automatically actuated by springs 110. In particular, in response to removable fan 102A being removed from server chassis 100, flaps 106A and 106B can automatically close.

In one embodiment, the flaps 106 can be in the open configuration when removable fan 102 is inserted in the server chassis 100. For example, removable fan 102B can be inserted into the server chassis 100. Flaps 106C and 106D are coupled to the server chassis 100 by shafts 108. Springs 110 can be coupled to shafts 108. The flaps 106C and 106D can be automatically actuated by springs 110. In response to removable fan 102B being inserted into server chassis 100, flaps 106C and 106D can automatically open.

Flaps 106 can have various arrangements for preventing airflow. In one embodiment, each opening on server chassis 100 can include one flap. In another embodiment, each opening on server chassis 100 can include two flaps. In one embodiment, the two flaps can be arranged to open and close vertically. In another embodiment, the two flaps can be arranged to open and close horizontally. However, in the various embodiments, the number and arrangement of flaps can vary.

Flaps 106 can be composed of different materials. Flaps 106 can be composed of any material that can prevent the diversion of airflow and withstand the constant force exerted by the springs. In one embodiment, flaps 106 can be composed of aluminum or other light weight metals. In another embodiment, flaps 106 can be composed of a hard plastic or polymer. In still other embodiments, a combination of such materials can be used for flaps.

In some embodiments, flaps 106 and shutters 104 can be integrated into a single element. For example, flaps 106, as shown in FIGS. 4 and 5, can be divided into one or more shutters 104 as shown in FIGS. 2 and 3. The one or more shutters 104 can include one or more horizontal shafts to support the above-mentioned divisions.

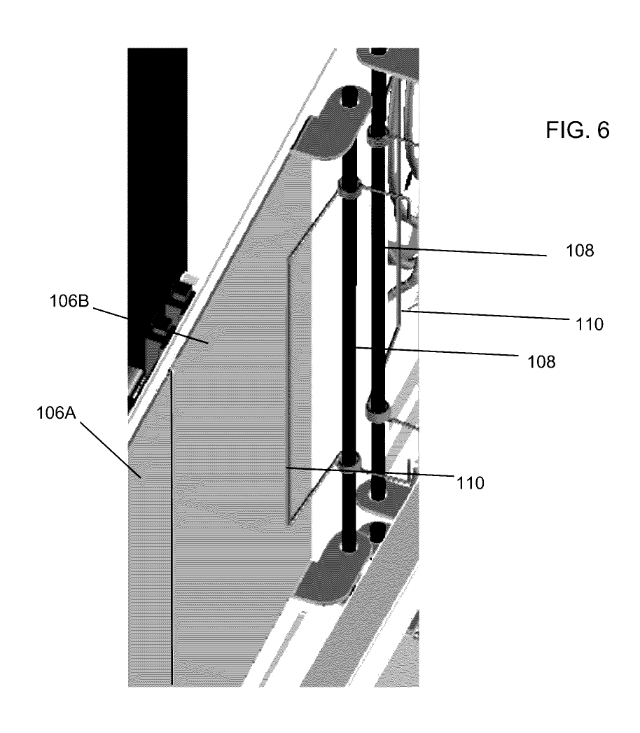

FIG. 6 illustrates an enlarged view of the flaps of a server chassis. Each flap can include a shaft (to couple the flap to the server chassis). Each shaft 108 can be associated with a spring 110 to enable automatic actuation of the flap upon insertion or removal of a removable fan. For example, in response to the removal of the removable fan, the arrangement of shafts 108, springs 110, and flaps 106A and 106B can be selected so as to cause flaps 106A and 106B to swing shut and close the opening. In particular, the flaps 106A and 106B can automatically close by the force exerted by the springs 110 against flaps 106A and 106B.

In some embodiments, the springs 110 can be configured to constantly exert a force on flaps 106A and 106B. Thus, upon insertion or removal of the removable fan, the constant force exerted by the springs 110 can automatically actuate the flaps 106A and 106B open or closed, respectively. The constant force exerted by springs 110 can be strong enough to actuate the flaps in response to removal or insertion of the removable fan. In another embodiment, springs 110 can be a hinge mechanism, a pivot mechanism, a lever mechanism, a weight mechanism, or any other type of mechanism for exerting a force on the flaps.

It is believed the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiments of the disclosure.

What is claimed is:

1. A system comprising:
a server chassis having an opening configured to receive at least one removable component through the opening;
the at least one removable component including at least one shutter, the at least one shutter transitionable between an open configuration and a closed configuration, wherein in the closed configuration the at least one shutter covers the removable component; and
at least one flap coupled to the server chassis and transitionable between an open configuration and a closed configuration, wherein in the closed configuration the at least one flap covers the opening.

2. The system of claim 1, wherein the removable component includes a fan.

3. The system of claim 1, further comprising the server chassis having a plurality of openings configured to receive a plurality of removable components through the plurality of openings.

4. The system of claim 1, wherein the at least one shutter is in the open configuration when the removable component is operating.

5. The system of claim 1, wherein the at least one shutter is in the closed configuration when the removable component is not operating.

6. The system of claim 1, further comprising a shaft for coupling the at least one flap to the server chassis.

7. The system of claim 1, further comprising a spring mechanism for actuating the at least one flap between the open configuration and a closed configuration.

8. The system of claim 7, wherein the spring mechanism is coupled to the at least one flap and to the shaft.

9. The system of claim 1, wherein the at least one flap is configured in the open configuration when the removable component is inserted into the opening of the server.

10. The system of claim 1, wherein the at least one flap is configured in the closed configuration when the removable component is not inserted into the opening of the server chassis.

11. The system of claim 1, wherein the server chassis includes two or more flaps.
